(19) United States
(12) Patent Application Publication
(10) Pub. No.: US 2024/0365678 A1
(43) Pub. Date: Oct. 31, 2024

(54) MAGNETIC MEMORY DEVICES

(71) Applicant: Samsung Electronics Co., Ltd., Suwon-si (KR)

(72) Inventors: Ki Woong Kim, Suwon-si (KR); Kwang Seok Kim, Suwon-si (KR); Seonggeon Park, Suwon-si (KR); Jeongchun Ryu, Suwon-si (KR)

(21) Appl. No.: 18/502,715

(22) Filed: Nov. 6, 2023

(30) Foreign Application Priority Data
Apr. 25, 2023 (KR) 10-2023-0054341

(51) Int. Cl. H10N 50/20; H10B 61/00; H10N 50/01; H10N 50/85

(52) U.S. Cl. CPC H10N 50/20; H10B 61/00; H10N 50/01; H10N 50/85

(57) ABSTRACT

A magnetic memory device includes: (i) a reference magnetic pattern and a free magnetic pattern stacked in vertical alignment relative to a surface of a substrate, and (ii) a tunnel barrier pattern extending between the reference magnetic pattern and the free magnetic pattern. The reference magnetic pattern includes: a first pinned pattern, and a second pinned pattern extending between the first pinned pattern and the tunnel barrier pattern, and an exchange coupling pattern, which extends between the first pinned pattern and the second pinned pattern and antiferromagnetically couples the first pinned pattern and the second pinned pattern to each other. The first pinned pattern includes a first magnetic pattern and a second magnetic pattern extending between the first magnetic pattern and the exchange coupling pattern. One of the first magnetic pattern and the second magnetic pattern includes: cobalt, platinum, and a first non-magnetic element comprising at least one of Nb, Cr, Mo, W, Zr, Hf, and Ti, whereas the other one of the first magnetic pattern and the second magnetic pattern includes cobalt.

### REFERENCE TO PRIORITY APPLICATION

This application claims priority under 35 U.S.C. § 119 to Korean Patent Application No. 10-2023-0054341, filed Apr. 25, 2023, the disclosure of which is hereby incorporated by reference.

### BACKGROUND

The present disclosure relates to integrated circuit devices and, more particularly, to magnetic memory devices and methods of manufacturing the same.

With the high speed and/or low power consumption of electronic devices, there is an increasing requirement for higher speed and/or lower operating voltages of semiconductor devices incorporated in an electronic device. To meet these requirements, magnetic memory devices have been proposed as semiconductor memory devices. Because magnetic memory devices may exhibit characteristics such as high-speed operation and/or non-volatility, they are being highlighted as next-generation semiconductor devices.

In general, a magnetic memory device may include a magnetic tunnel junction (MTJ) pattern; a MTJ pattern may include two magnetic substances and an insulating layer extending therebetween. Resistance of the MTJ pattern may vary depending on magnetization directions of the two magnetic substances. For example, when the magnetization directions of the two magnetic substances are antiparallel to each other, the MTJ pattern may have relatively high resistance, whereas when the magnetization directions of the two magnetic substances are in the same direction, the MTJ pattern may have relatively low resistance. As will be understood by those skilled in the art, data may be written/read using this high/low resistance difference.

As the electronic industry is highly developed, high integration and/or low power consumption of a magnetic memory device are being increasingly required. In addition, various studies are being conducted to improve the reliability of the magnetic memory device.

### SUMMARY

An object of the present disclosure is to provide a magnetic memory device with improved tunnel magnetoresistance (TMR) characteristics and exchange coupling characteristics of a magnetic tunnel junction pattern, and a method of manufacturing the same.

An object of the present disclosure is to provide a magnetic memory device with improved high-temperature reliability, and a method of manufacturing the same.

A magnetic memory device according to some embodiments of the present disclosure may include a reference magnetic pattern and a free magnetic pattern sequentially stacked on a substrate, and a tunnel barrier pattern between the reference magnetic pattern and the free magnetic pattern. The reference magnetic pattern may include a first pinned pattern, a second pinned pattern between the first pinned pattern and the tunnel barrier pattern, and an exchange coupling pattern (ECP) extending between the first pinned pattern and the second pinned pattern. This ECP is configured to antiferromagnetically couple the first pinned pattern and the second pinned pattern to each other. The first pinned pattern includes a first magnetic pattern and a second magnetic pattern, which extends between the first magnetic pattern and the ECP. One of the first magnetic pattern and the second magnetic pattern includes cobalt, platinum, and a first non-magnetic element, and the first non-magnetic element includes at least one of Nb, Cr, Mo, W, Zr, Hf, and Ti. The other one of the first magnetic pattern and the second magnetic pattern includes cobalt.

A magnetic memory device according to some embodiments of the present disclosure may include a reference magnetic pattern and a free magnetic pattern sequentially stacked on a substrate, a tunnel barrier pattern between the reference magnetic pattern and the free magnetic pattern, a polarization enhancement pattern between the reference magnetic pattern and the tunnel barrier pattern, and a blocking pattern between the reference magnetic pattern and the polarization enhancement pattern. The blocking pattern may include a first blocking pattern including tungsten and a second blocking pattern extending between the first blocking pattern and the polarization enhancement pattern and including a ferromagnetic element and molybdenum. The second blocking pattern may be in contact with the polarization enhancement pattern. The reference magnetic pattern may include a first pinned pattern, a second pinned pattern between the first pinned pattern and the blocking pattern, and an exchange coupling pattern between the first pinned pattern and the second pinned pattern. The first pinned pattern may include cobalt, platinum, and a first non-magnetic element, and the first non-magnetic element may include at least one of Nb, Cr, Mo, W, Zr, Hf, and Ti.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram illustrating a unit memory cell of a magnetic memory device according to some embodiments of the present disclosure.

FIGS. 2 to 7 are cross-sectional views of a magnetic memory device according to some embodiments of the present disclosure.

FIGS. 8 to 11 are cross-sectional views illustrating a method of manufacturing a magnetic memory device according to some embodiments of the present disclosure.

FIG. 12 is a plan view of a magnetic memory device according to some embodiments of the present disclosure.

FIG. 13 is a cross-sectional view taken along I-I′ of FIG. 12.

FIG. 14 is a circuit diagram schematically illustrating a memory cell of a magnetic memory device according to some embodiments of the present disclosure.

FIG. 15 is a cross-sectional view of a magnetic memory device according to some embodiments of the present disclosure.

### DETAILED DESCRIPTION

Hereinafter, the present disclosure will be described in detail by describing embodiments of the present disclosure with reference to the accompanying drawings.

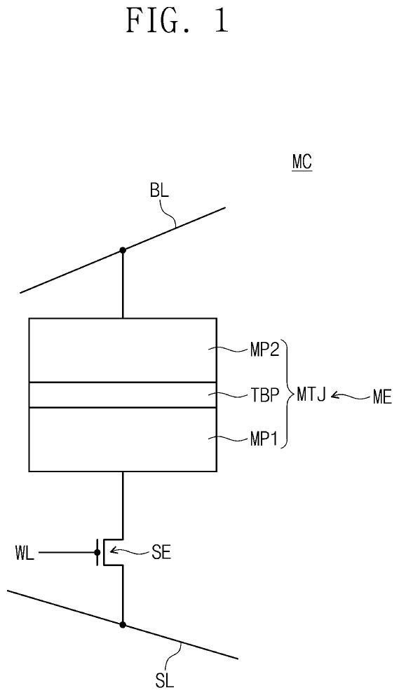

FIG. 1 is a circuit diagram illustrating a unit memory cell of a magnetic memory device according to some embodiments of the present disclosure. Referring to FIG. 1, a unit memory cell MC may include a memory element ME and a selection element SE. The memory element ME and the selection element SE may be electrically connected to each other in series. The memory element ME may be connected between a bit line BL and the selection element SE. The selection element SE may be connected between the memory element ME and a source line SL, and may be controlled by a word line WL. The selection element SE may include, for example, a bipolar transistor or a MOS field effect transistor.

The memory element ME may include a magnetic tunnel junction pattern MTJ including magnetic patterns MP1 and MP2 spaced apart from each other and a tunnel barrier pattern TBP between the magnetic patterns MP1 and MP2. One of the magnetic patterns MP1 and MP2 may be a reference magnetic pattern having a magnetization direction fixed in one direction regardless of an external magnetic field under a normal use environment. The other of the magnetic patterns MP1 and MP2 may be a free magnetic pattern in which a magnetization direction is changed between two stable magnetization directions by an external magnetic field. An electrical resistance of the magnetic tunnel junction pattern MTJ may be much higher when magnetization directions of the reference magnetic pattern and the free magnetic pattern are antiparallel to each other than when magnetization directions are parallel to each other. That is, the electrical resistance of the magnetic tunnel junction pattern MTJ may be adjusted by changing the magnetization direction of the free magnetic pattern. Accordingly, the memory element ME may store data in the unit memory cell MC using a difference in electrical resistance depending on magnetization directions of the reference magnetic pattern and the free magnetic pattern.

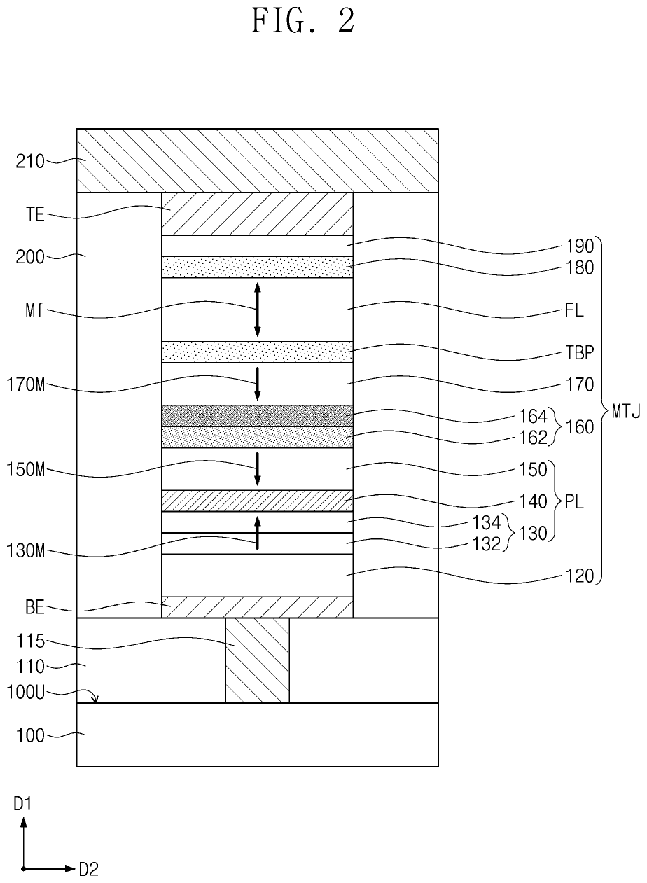

FIG. 2 is a cross-sectional view of a magnetic memory device according to some embodiments of the present disclosure. Referring to FIG. 2, a first interlayer insulating layer 110 may extend on a substrate 100, and a lower contact plug 115 may extend within a contact hole in the first interlayer insulating layer 110. The substrate 100 may be a semiconductor substrate including silicon, silicon on insulator (SOI), silicon germanium (SiGe), germanium (Ge), gallium arsenide (GaAs), or the like. The first interlayer insulating layer 110 may include, for example, silicon oxide, silicon nitride, and/or silicon oxynitride.

The lower contact plug 115 may pass through the first interlayer insulating layer 110 and may be electrically connected to the substrate 100. A selection element (SE in FIG. 1) may extend in the substrate 100. The selection element may be a switch, such as a field effect transistor. The lower contact plug 115 may be electrically connected to one terminal (e.g., a source/drain terminal) of the selection element. The lower contact plug 115 may include a doped semiconductor material (e.g., doped silicon), a metal (e.g., tungsten, titanium, and/or tantalum), a metal-semiconductor compound (e.g., metal silicide), and a conductive metal nitride (e.g., titanium nitride, tantalum nitride, and/or tungsten nitride).

A lower electrode BE, a magnetic tunnel junction pattern MTJ, and an upper electrode TE may be sequentially stacked on the lower contact plug 115 in a first direction D1 perpendicular to an upper surface 100U of the substrate 100. The lower electrode BE may extend between the lower contact plug 115 and the magnetic tunnel junction pattern MTJ, and the magnetic tunnel junction pattern MTJ may extend between the lower electrode BE and the upper electrode TE. The lower electrode BE may be electrically connected to the lower contact plug 115. The lower electrode BE may include, for example, a conductive metal nitride (e.g., titanium nitride or tantalum nitride). The upper electrode TE may include at least one of a metal (e.g., Ta, W, Ru, Ir, etc.) and a conductive metal nitride (e.g., TiN).

The magnetic tunnel junction pattern MTJ may include a reference magnetic pattern PL, a free magnetic pattern FL, and a tunnel barrier pattern TBP between the reference magnetic pattern PL and the free magnetic pattern FL. According to some embodiments, the reference magnetic pattern PL may extend between the lower electrode BE and the tunnel barrier pattern TBP, and the free magnetic pattern FL may extend between the upper electrode TE and the tunnel barrier pattern TBP.

The reference magnetic pattern PL may include a first pinned pattern 130, a second pinned pattern 150 between the first pinned pattern 130 and the tunnel barrier pattern TBP, and an exchange coupling pattern 140 between the first pinned pattern 130 and the second pinned pattern 150. The first pinned pattern 130 may include a first magnetic pattern 132 and a second magnetic pattern 134 between the first magnetic pattern 132 and the exchange coupling pattern 140. One of the first magnetic pattern 132 and the second magnetic pattern 134 may include cobalt (Co), platinum (Pt), and a first non-magnetic element. The first non-magnetic element may include at least one of Nb, Cr, Mo, W, Zr, Hf, and Ti. The other one of the first magnetic pattern 132 and the second magnetic pattern 134 may include cobalt (Co). For example, the first magnetic pattern 132 may include CoPtCr, and the second magnetic pattern 134 may include Co. As another example, the first magnetic pattern 132 may include Co, and the second magnetic pattern 134 may include CoPtCr. That is, the first pinned pattern 130 may have a multilayer structure in which a CoPtCr layer and a Co layer are stacked. The first pinned pattern 130 may have a first perpendicular magnetization direction 130M perpendicular to an interface between the tunnel barrier pattern TBP and the free magnetic pattern FL. For example, the first perpendicular magnetization direction 130M may be perpendicular to the upper surface 100U of the substrate 100.

Advantageously, the exchange coupling pattern 140 may antiferromagnetically couple the first pinned pattern 130 to the second pinned pattern 150. The exchange coupling pattern 140 may include a non-magnetic material having anti-ferromagnetic coupling characteristics. For example, the exchange coupling pattern 140 may include at least one of iridium (Ir) and ruthenium (Ru).

The second pinned pattern 150 may include a ferromagnetic element, for example, cobalt (Co). The second pinned pattern 150 may be a single layer formed of a ferromagnetic element, such as a single layer of cobalt (Co). The second pinned pattern 150 may have a hexagonal close packed lattice (HCP) crystal structure. The second pinned pattern 150 may have a second perpendicular magnetization direction 150M perpendicular to the interface between the tunnel barrier pattern TBP and the free magnetic pattern FL. For example, the second perpendicular magnetization direction 150M may be perpendicular to the upper surface 100U of the substrate 100. The second pinned pattern 150 may be antiferromagnetically coupled to the first pinned pattern 130 by the exchange coupling pattern 140. Accordingly, the second perpendicular magnetization direction 150M may be antiparallel to the first perpendicular magnetization direction 130M of the first pinned pattern 130.

The magnetic tunnel junction pattern MTJ may further include a seed pattern 120 between the lower electrode BE and the reference magnetic pattern PL, a polarization enhancement pattern 170 between the tunnel barrier pattern TBP and the reference magnetic pattern PL, and a blocking pattern 160 between the polarization enhancement pattern 170 and the reference magnetic pattern PL.

The seed pattern 120 may include a material that helps crystal growth of the reference magnetic pattern PL. The seed pattern 120 may include, for example, at least one of chromium (Cr), iridium (Ir), and ruthenium (Ru).

The polarization enhancement pattern 170 may include a magnetic material that induces an interfacial perpendicular magnetic anisotropy at an interface between the tunnel barrier pattern TBP and the polarization enhancement pattern 170. The polarization enhancement pattern 170 may include a magnetic material having a body centered cubic (BCC) structure and may further include a non-magnetic element. For example, the polarization enhancement pattern 170 may include at least one of cobalt (Co), iron (Fe), and nickel (Ni), and further include at least one of boron (B), zinc (Zn), aluminum (Al), titanium (Ti), ruthenium (Ru), tantalum (Ta), silicon (Si), silver (Ag), gold (Au), copper (Cu), carbon (C), and nitrogen (N). For example, the polarization enhancement pattern 170 may include cobalt-iron (CoFe) or nickel-iron (NiFe), and may further include boron (B). For example, the polarization enhancement pattern 170 may include cobalt-iron-boron (CoFeB). The polarization enhancement pattern 170 may have perpendicular magnetization characteristics due to magnetic anisotropy induced by bonding the tunnel barrier pattern TBP and the polarization enhancement pattern 170. The polarization enhancement pattern 170 may have a third perpendicular magnetization direction 170M perpendicular to the interface between the tunnel barrier pattern TBP and the free magnetic pattern FL. For example, the third perpendicular magnetization direction 170M may be perpendicular to the upper surface 100U of the substrate 100. The third perpendicular magnetization direction 170M may be parallel to the second perpendicular magnetization direction 150M of the second pinned pattern 150.

At least a portion of the blocking pattern 160 may be amorphous, according to some embodiments of the invention. The blocking pattern 160 may include a first blocking pattern 162 and a second blocking pattern 164 between the first blocking pattern 162 and the polarization enhancement pattern 170. The blocking pattern 160 may have a multilayer structure including the first blocking pattern 162 and the second blocking pattern 164. The first blocking pattern 162 may include tungsten (W), and the second blocking pattern 164 may include molybdenum (Mo). The second blocking pattern 164 may be amorphous, according to some embodiments of the invention.

The first blocking pattern 162 may further include a first ferromagnetic element, and the first ferromagnetic element may include at least one of cobalt (Co), iron (Fe), and nickel (Ni). The first blocking pattern 162 may further include boron (B). For example, the first blocking pattern 162 may include at least one of W, FeBW, CoBW, and CoFeBW. The first blocking pattern 162 may prevent boron (B) in layers disposed thereon from diffusing into the reference magnetic pattern PL (e.g., into the second pinned pattern 150).

The second blocking pattern 164 may further include a second ferromagnetic element, and the second ferromagnetic element may include at least one of cobalt (Co), iron (Fe), and nickel (Ni). The second blocking pattern 164 may further include boron (B). For example, the second blocking pattern 164 may include at least one of CoMo, FeMo, CoFeMo, and CoFeBMo. According to some embodiments, the second blocking pattern 164 may include molybdenum (Mo) or an alloy of molybdenum (Mo) and the second ferromagnetic element. In this case, a content of the molybdenum (Mo) in the second blocking pattern 164 may be about 70 atom % (at %) to about 100 at %, and thus, the second blocking pattern 164 may be in an amorphous phase. According to other embodiments, the second blocking pattern 164 may include molybdenum (Mo), boron (B), and the second ferromagnetic element, for example, CoFeBMo. In this case, the second blocking pattern 164 may have an amorphous phase, and a content of molybdenum (Mo) in the second blocking pattern 164 may be smaller than a content of boron (B) in the second blocking pattern 164. For example, the content of molybdenum (Mo) in the second blocking pattern 164 may be less than or equal to 10 at %. As the second blocking pattern 164 has an amorphous phase, crystallinity of the reference magnetic pattern PL disposed thereunder may be blocked from being transferred to the polarization enhancement pattern 170, and growth of a body centered cubic (BCC) crystal structure of the polarization enhancement pattern 170 may be facilitated.

The first blocking pattern 162 may be in direct contact with the second pinned pattern 150 of the reference magnetic pattern PL. The second blocking pattern 164 may extend between the first blocking pattern 162 and the polarization enhancement pattern 170, and may be in direct contact with the first blocking pattern 162 and the polarization enhancement pattern 170.

The polarization enhancement pattern 170 may be ferromagnetically coupled to the second pinned pattern 150 by the blocking pattern 160. Accordingly, the third perpendicular magnetization direction 170M of the polarization enhancement pattern 170 may be fixed parallel to the second perpendicular magnetization direction 150M of the second pinned pattern 150. In some embodiments, the tunnel barrier pattern TBP may include at least one of a magnesium (Mg) oxide layer, a titanium (Ti) oxide layer, an aluminum (Al) oxide layer, a magnesium-zinc (Mg—Zn) oxide layer, or a magnesium-boron (Mg—B) oxide layer.

The free magnetic pattern FL may have perpendicular magnetization characteristics due to magnetic anisotropy induced by bonding the free magnetic pattern FL and the tunnel barrier pattern TBP. A magnetization direction Mf of the free magnetic pattern FL may be changed to be parallel or antiparallel to the third perpendicular magnetization direction 170M of the polarization enhancement pattern 170. When the magnetization direction Mf of the free magnetic pattern FL is parallel to the third perpendicular magnetization direction 170M of the polarization enhanced pattern 170, the magnetic tunnel junction pattern MTJ may have a relatively low resistance value; however, when the magnetization direction Mf of the free magnetic pattern FL is antiparallel to the third perpendicular magnetization direction 170M of the polarization enhanced pattern 170, the magnetic tunnel junction pattern MTJ may have a relatively high resistance value. The free magnetic pattern FL may include a magnetic material capable of inducing the magnetic anisotropy at an interface between the free magnetic pattern FL and the tunnel barrier pattern TBP. For example, the free magnetic pattern FL may include cobalt-iron-boron (CoFeB).

The magnetic tunnel junction pattern MTJ may further include a capping pattern 190 between the upper electrode TE and the free magnetic pattern FL, and an upper non-magnetic pattern 180 between the capping pattern 190 and the free magnetic pattern FL. The upper non-magnetic pattern 180 may include at least one of a magnesium (Mg) oxide layer, a titanium (Ti) oxide layer, an aluminum (Al) oxide layer, a magnesium-zinc (Mg—Zn) oxide layer, or a magnesium-boron (Mg—B) oxide layer. For example, the upper non-magnetic pattern 180 may include the same material as the tunnel barrier pattern TBP. Magnetic anisotropy induced at an interface between the upper nonmagnetic pattern 180 and the free magnetic pattern FL may improve magnetic anisotropy of the free magnetic pattern FL. The capping pattern 190 may prevent deterioration of the free magnetic pattern FL. For example, the capping pattern 190 may include at least one of tantalum (Ta), ruthenium (Ru), molybdenum (Mo), aluminum (Al), copper (Cu), gold (Au), silver (Ag), or titanium (Ti), tantalum nitride (TaN) and titanium nitride (TiN).

A second interlayer insulating layer 200 may extend on the first interlayer insulating layer 110 and cover side surfaces of the lower electrode BE, the magnetic tunnel junction pattern MTJ, and the upper electrode TE. The second interlayer insulating layer 200 may include, for example, silicon oxide, silicon nitride, and/or silicon oxynitride.

An upper wiring 210 may extend on the second interlayer insulating layer 200 and may be connected to the upper electrode TE. The upper wiring 210 may extend in a second direction D2 parallel to the upper surface 100U of the substrate 100. The upper wiring 210 may be connected to the magnetic tunnel junction pattern MTJ through the upper electrode TE and may function as the bit line BL of FIG. 1. The upper wiring 210 may include at least one of a metal (e.g., copper) and a conductive metal nitride.

When a high-temperature process of 400° C. or higher is performed on the magnetic tunnel junction pattern MTJ, crystallinity of the polarization enhancement pattern 170 and the reference magnetic pattern PL may be deteriorated due to diffusion of boron (B) in the magnetic tunnel junction pattern MTJ. As a result, tunnel magnetoresistance (TMR) characteristics of the magnetic tunnel junction pattern MTJ and exchange field (Hex) characteristics of the reference magnetic pattern PL may be deteriorated.

According to the concept of the present disclosure, the first pinned pattern 130 may include cobalt (Co), platinum (Pt), and the first non-magnetic element. As the first pinned pattern 130 includes the first non-magnetic element, saturation magnetization (Mst) of the first pinned pattern 130 may be reduced compared to the CoPt pinned layer, and coercive force (Hc) of the first pinned pattern 130 may increase. As the first pinned pattern 130 has a relatively small saturation magnetization (Mst), exchange field (Hex) between the first pinned pattern 130 and the second pinned pattern 150 may increase. In addition, because the first pinned pattern 130 has a relatively high coercive force (Hc), its heat tolerance to a high-temperature process of 400° C. or higher may be increased. And, because the first pinned pattern 130 includes the first non-magnetic element, surface roughness of the first pinned pattern 130 may be reduced.

In addition, the blocking pattern 160 may have a multilayer structure including the first blocking pattern 162 and the second blocking pattern. As the first blocking pattern 162 includes tungsten, diffusion of boron into the magnetic tunnel junction pattern MTJ may be prevented. The second blocking pattern 164 may include molybdenum and may have an amorphous phase. Accordingly, transfer of crystallinity of the reference magnetic pattern PL to the polarization enhancement pattern 170 may be blocked, and crystal growth of the polarization enhancement pattern 170 may be facilitated. As the first blocking pattern 162 and the second blocking pattern 164 include tungsten and molybdenum having relatively high melting points, respectively, deterioration of crystallinity of the reference magnetic pattern PL and the polarization enhancement pattern 170 may be prevented, even when a high-temperature process of 400° C. or higher is performed. Accordingly, the tunnel magnetoresistance (TMR) characteristics and exchange coupling characteristics of the magnetic tunnel junction pattern MTJ may be improved, and high-temperature reliability of the magnetic memory device including the magnetic tunnel junction pattern MTJ may be improved.

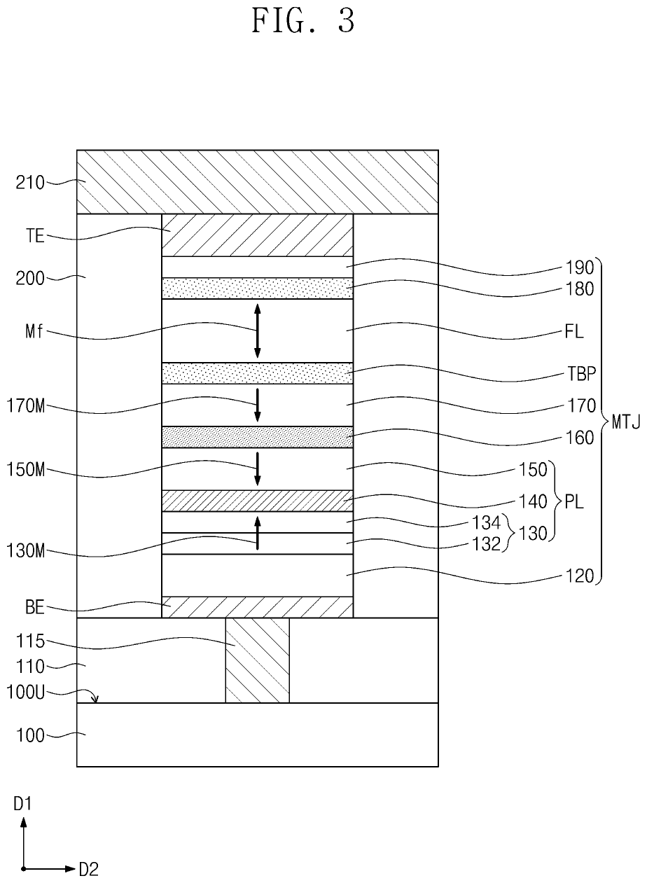

FIG. 3 is a cross-sectional view of a magnetic memory device according to some embodiments of the present disclosure. For simplicity of description, differences from the magnetic memory device described with reference to FIG. 2 will be mainly described. Referring to FIG. 3, a blocking pattern 160 may have a single-layer structure and may include a ferromagnetic element, boron, and tungsten. The ferromagnetic element may include at least one of cobalt (Co), iron (Fe), and nickel (Ni). For example, the blocking pattern 160 may include FeBW. The blocking pattern 160 may extend between the second pinned pattern 150 of the reference magnetic pattern PL and the polarization enhancement pattern 170, and may in direct contact with the second pinned pattern 150 and the polarization enhancement pattern 170. The polarization enhancement pattern 170 may be ferromagnetically coupled to the second pinned pattern 150 by the blocking pattern 160. Except for the above differences, the magnetic memory device according to the present embodiments is substantially the same as the magnetic memory device described with reference to FIG. 2.

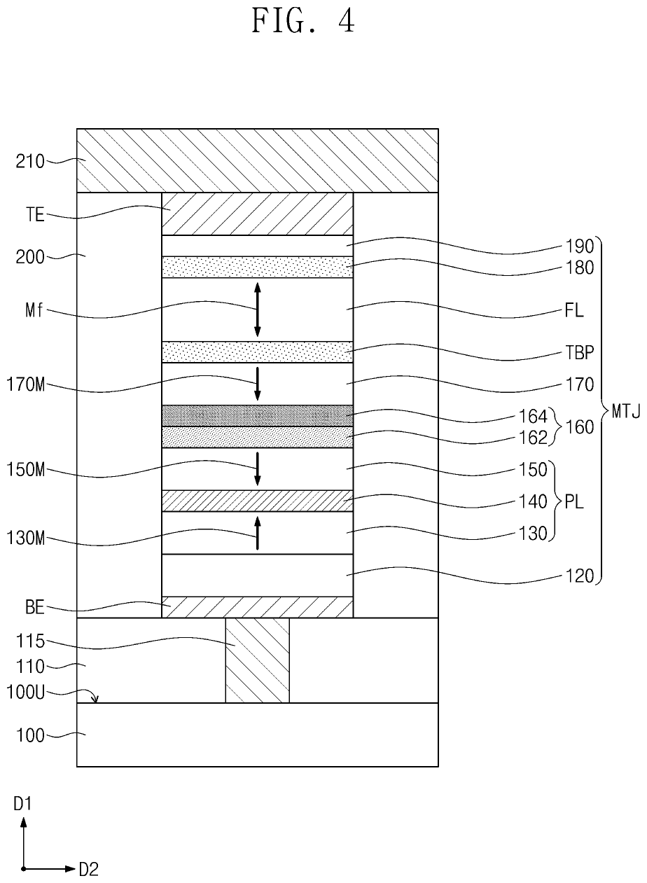

FIG. 4 is a cross-sectional view of a magnetic memory device according to some embodiments of the present disclosure. For simplicity of description, differences from the magnetic memory device described with reference to FIG. 2 will be mainly described. Referring to FIG. 4, a reference magnetic pattern PL may include a first pinned pattern 130, a second pinned pattern 150 between the first pinned pattern 130 and the tunnel barrier pattern TBP, and an exchange coupling pattern 140 between the first pinned pattern 130 and the second pinned pattern 150. The first pinned pattern 130 may include cobalt (Co) and platinum (Pt), and may not include the first non-magnetic element. The first pinned pattern 130 may include, for example, CoPt. The second pinned pattern 150 and the exchange coupling pattern 140 may be substantially the same as the second pinned pattern 150 and the exchange coupling pattern 140 described with reference to FIG. 2, respectively.

The first pinned pattern 130 may have a first perpendicular magnetization direction 130M perpendicular to an interface between the tunnel barrier pattern TBP and the free magnetic pattern FL. For example, the first perpendicular magnetization direction 130M may be perpendicular to the upper surface 100U of the substrate 100. The second pinned pattern 150 may be antiferromagnetically coupled to the first pinned pattern 130 by the exchange coupling pattern 140. Accordingly, the second perpendicular magnetization direction 150M of the second pinned pattern 150 may be antiparallel to the first perpendicular magnetization direction 130M of the first pinned pattern 130. Except for the above described differences, the magnetic memory device according to the present embodiment may be substantially the same as the magnetic memory device described with reference to FIG. 2.

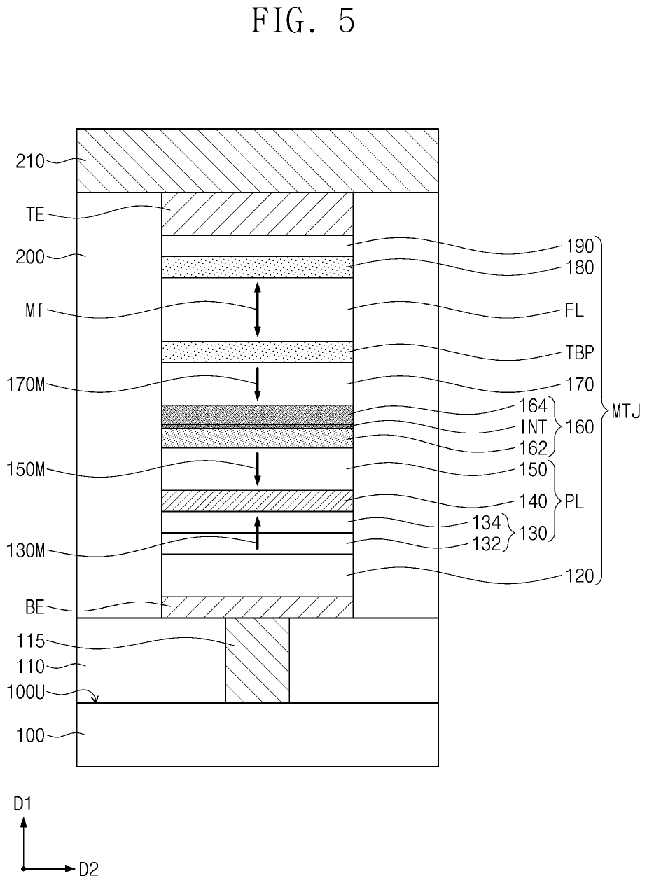

FIG. 5 is a cross-sectional view of a magnetic memory device according to some embodiments of the present disclosure. For simplicity of description, differences from the magnetic memory device described with reference to FIG. 2 will be mainly described. Referring to FIG. 5, a blocking pattern 160 may include a first blocking pattern 162, a second blocking pattern 164, and an interface layer INT extending between the first blocking pattern 162 and the second blocking pattern 164. The interface layer INT may include at least one of tungsten (W), molybdenum (Mo), boron (B), the first ferromagnetic element, and the second ferromagnetic element. And, except for the above differences, the magnetic memory device according to the present embodiments may be substantially the same as the magnetic memory device described with reference to FIG. 2.

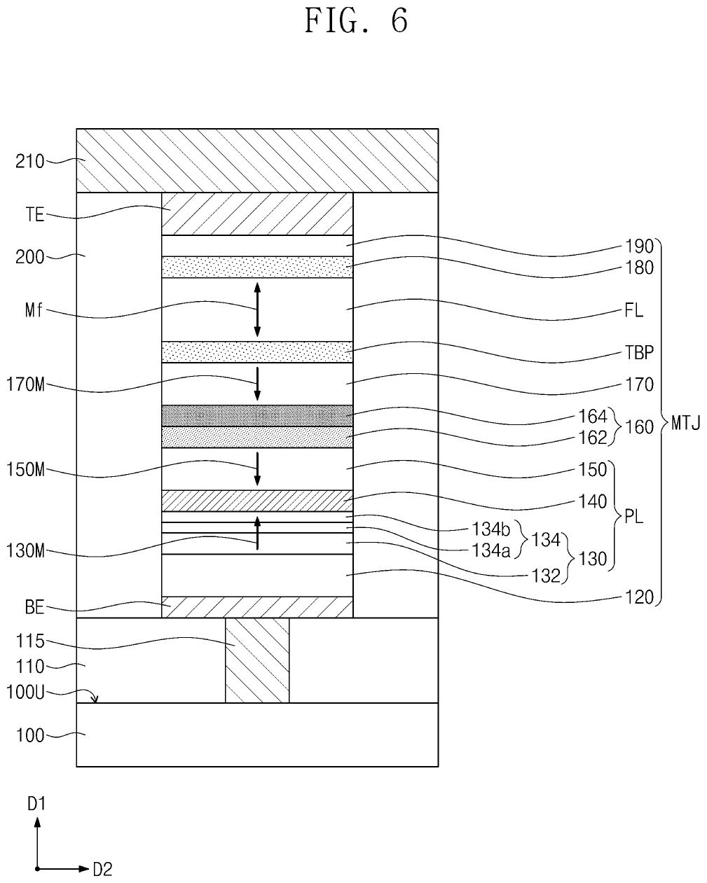

FIG. 6 is a cross-sectional view of a magnetic memory device according to some embodiments of the present disclosure. For simplicity of description, differences from the magnetic memory device described with reference to FIG. 2 will be mainly described. Referring to FIG. 6, a reference magnetic pattern PL may include a first pinned pattern 130, a second pinned pattern 150 between the first pinned pattern 130 and the tunnel barrier pattern TBP, and an exchange coupling pattern 140 between the first pinned pattern 130 and the second pinned pattern 150. The second pinned pattern 150 and the exchange coupling pattern 140 are substantially the same as the second pinned pattern 150 and the exchange coupling pattern 140 described with reference to FIG. 2, respectively.

The first pinned pattern 130 may include a first magnetic pattern 132 and a second magnetic pattern 134 between the first magnetic pattern 132 and the exchange coupling pattern 140. The second magnetic pattern 134 may include a first sub magnetic pattern 134a and a second sub magnetic pattern 134b between the first sub magnetic pattern 134a and the exchange coupling pattern 140. According to some embodiments, the first magnetic pattern 132 may include cobalt (Co), platinum (Pt), and a first non-magnetic element. The first non-magnetic element may include at least one of Nb, Cr, Mo, W, Zr, Hf, and Ti. For example, the first magnetic pattern 132 may include CoPtCr. One of the first sub magnetic pattern 134a and the second sub magnetic pattern 134b may include cobalt (Co), and the other one of the first sub magnetic pattern 134a and the second sub magnetic pattern 134b may include cobalt (Co) and platinum (Pt). For example, the second magnetic pattern 134 may have a multilayer structure in which a CoPt layer and a Co layer are stacked.

According to other embodiments, the first magnetic pattern 132 may include cobalt (Co) and platinum (Pt). For example, the first magnetic pattern 132 may include CoPt. One of the first sub magnetic pattern 134a and the second sub magnetic pattern 134b may include cobalt (Co), platinum (Pt), and a first non-magnetic element. The first non-magnetic element may include at least one of Nb, Cr, Mo, W, Zr, Hf, and Ti. The other one of the first sub magnetic pattern 134a and the second sub magnetic pattern 134b may include cobalt (Co). For example, the first sub magnetic pattern 134a may include CoPtCr, and the second sub magnetic pattern 134b may include Co. As another example, the first sub magnetic pattern 134a may include Co, and the second sub magnetic pattern 134b may include CoPtCr. That is, the second magnetic pattern 134 may have a multilayer structure in which a CoPtCr layer and a Co layer are stacked.

The first pinned pattern 130 may have a first perpendicular magnetization direction 130M perpendicular to an interface between the tunnel barrier pattern TBP and the free magnetic pattern FL. For example, the first perpendicular magnetization direction 130M may be perpendicular to the upper surface 100U of the substrate 100. The second pinned pattern 150 may be antiferromagnetically coupled to the first pinned pattern 130 by the exchange coupling pattern 140. Accordingly, the second perpendicular magnetization direction 150M of the second pinned pattern 150 may be antiparallel to the first perpendicular magnetization direction 130M of the first pinned pattern 130. Except for the above differences, the magnetic memory device according to the present embodiments may be substantially the same as the magnetic memory device described with reference to FIG. 2.

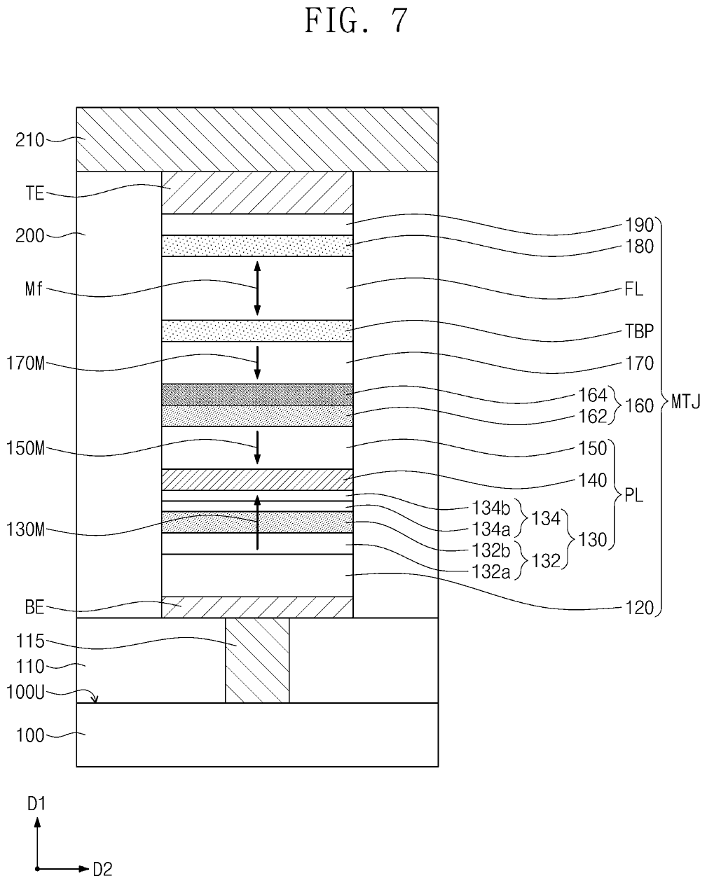

FIG. 7 is a cross-sectional view of a magnetic memory device according to some embodiments of the present disclosure. For simplicity of description, differences from the magnetic memory device described with reference to FIG. 2 will be mainly described. Referring to FIG. 7, a reference magnetic pattern PL may include a first pinned pattern 130, a second pinned pattern 150 between the first pinned pattern 130 and the tunnel barrier pattern TBP, and an exchange coupling pattern 140 between the first pinned pattern 130 and the second pinned pattern 150. The second pinned pattern 150 and the exchange coupling pattern 140 are substantially the same as the second pinned pattern 150 and the exchange coupling pattern 140 described with reference to FIG. 2, respectively. The first pinned pattern 130 may include a first magnetic pattern 132 and a second magnetic pattern 134 between the first magnetic pattern 132 and the exchange coupling pattern 140. The second magnetic pattern 134 may include a first sub magnetic pattern 134a and a second sub magnetic pattern 134b between the first sub magnetic pattern 134a and the exchange coupling pattern 140. The first magnetic pattern 132 may include a third sub magnetic pattern 132a and a sub non-magnetic pattern 132b between the third sub magnetic pattern 132a and the second magnetic pattern 134.

According to some embodiments, the third sub magnetic pattern 132a may include cobalt (Co) and platinum (Pt). The sub non-magnetic pattern 132b may include a first non-magnetic element. The first non-magnetic element may include at least one of Nb, Cr, Mo, W, Zr, Hf, and Ti. For example, the third sub magnetic pattern 132a may include CoPt, and the sub non-magnetic pattern 132b may include Cr. In this case, the first magnetic pattern 132 may have a multilayer structure in which a CoPt layer and a Cr layer are stacked.

According to other embodiments, the third sub magnetic pattern 132a may include cobalt (Co), platinum (Pt), and a second non-magnetic element, and the sub non-magnetic pattern 132b may include the first non-magnetic element. The second non-magnetic element may include at least one of Nb, Cr, Mo, W, Zr, Hf, and Ti. For example, the third sub magnetic pattern 132a may include CoPtCr, and the sub non-magnetic pattern 132b may include Cr. In this case, the first magnetic pattern 132 may have a multilayer structure in which a CoPtCr layer and a Cr layer are stacked.

According to some embodiments, one of the first sub magnetic pattern 134a and the second sub magnetic pattern 134b may include cobalt (Co) and platinum (Pt), and the other one of the first sub magnetic pattern 134a and the second sub magnetic pattern 134b may include cobalt. For example, the first sub magnetic pattern 134a may include CoPt, and the second sub magnetic pattern 134b may include Co. As another example, the first sub magnetic pattern 134a may include Co, and the second sub magnetic pattern 134b may include CoPt. That is, the second magnetic pattern 134 may have a multilayer structure in which a CoPt layer and a Co layer are stacked.

According to other embodiments, one of the first sub magnetic pattern 134a and the second sub magnetic pattern 134b may include cobalt (Co), platinum (Pt), and a first non-magnetic element. The first non-magnetic element may include at least one of Nb, Cr, Mo, W, Zr, Hf, and Ti. The other one of the first sub magnetic pattern 134a and the second sub magnetic pattern 134b may include cobalt. For example, the first sub magnetic pattern 134a may include CoPtCr, and the second sub magnetic pattern 134b may include Co. As another example, the first sub magnetic pattern 134a may include Co, and the second sub magnetic pattern 134b may include CoPtCr. That is, the second magnetic pattern 134 may have a multilayer structure in which a CoPtCr layer and a Co layer are stacked. Except for the above differences, the magnetic memory device according to the present embodiments may be substantially the same as the magnetic memory device described with reference to FIG. 2.

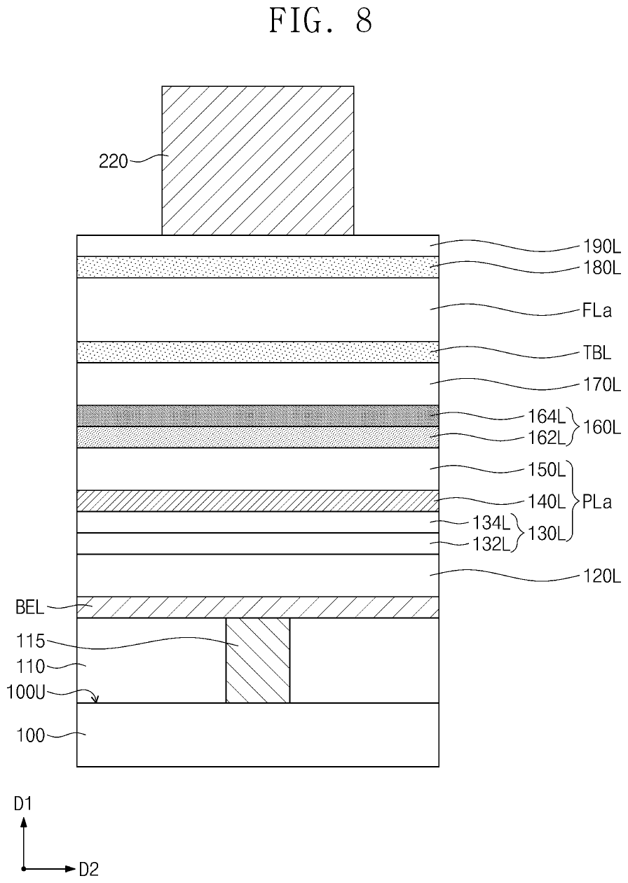

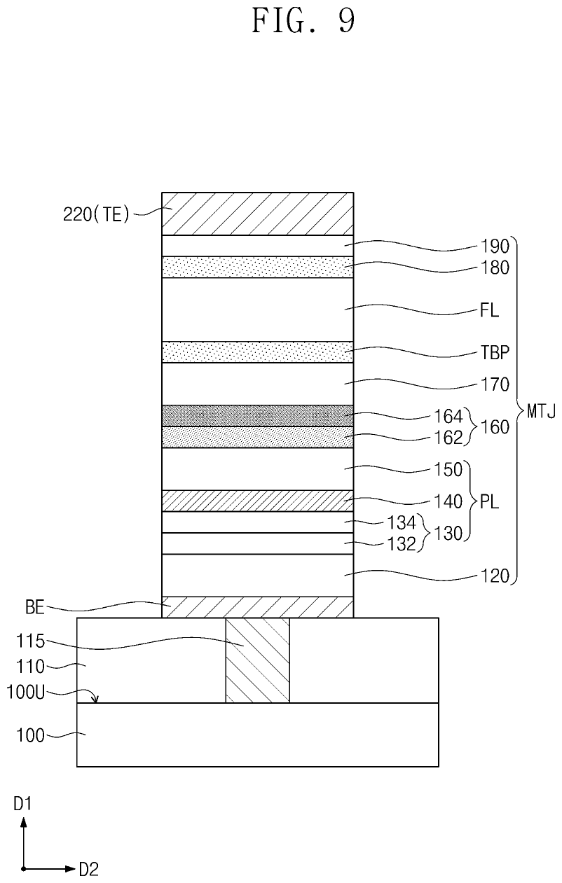

FIGS. 8 and 9 are cross-sectional views illustrating a method of manufacturing a magnetic memory device according to some embodiments of the present disclosure. For simplicity of explanation, descriptions overlapping those of the magnetic memory device described with reference to FIGS. 2 to 7 will be omitted. Referring to FIG. 8, a first interlayer insulating layer 110 may be formed on the substrate 100, and a lower contact plug 115 may be formed in the first interlayer insulating layer 110. The lower contact plug 115 may be formed to pass through the first interlayer insulating layer 110, and may be electrically connected to one terminal (e.g., a source/drain terminal) of a selection element (SE in FIG. 1) in the substrate 100.

A lower electrode layer BEL, a seed layer 120L, a reference magnetic layer PLa, a blocking layer 160L, a polarization enhancement layer 170L, a tunnel barrier layer TBL, a free magnetic layer FLa, an upper non-magnetic layer 180L and a capping layer 190L may be sequentially stacked on the first insulating interlayer 110. The reference magnetic layer PLa may include a first pinned layer 130L, an exchange coupling layer 140L, and a second pinned layer 150L sequentially stacked on the seed layer 120L. The first pinned layer 130L may include a first magnetic layer 132L and a second magnetic layer 134L sequentially stacked on the seed layer 120L.

According to some embodiments, one of the first magnetic layer 132L and the second magnetic layer 134L may include cobalt (Co), platinum (Pt), and a first non-magnetic element, and the first non-magnetic element may include at least one of Nb, Cr, Mo, W, Zr, Hf, and Ti. The other one of the first magnetic layer 132L and the second magnetic layer 134L may include cobalt (Co).

In some embodiments, as described with reference to FIGS. 6 and 7, the second magnetic layer 134L may include a first sub magnetic layer and a second sub magnetic layer sequentially stacked on the first magnetic layer 132L. For example, one of the first sub magnetic layer and the second sub magnetic layer may include cobalt (Co), and the other one of the first sub magnetic layer and the second sub magnetic layer may include cobalt (Co) and platinum (Pt). The second magnetic layer 134L may be formed to have a multilayer structure in which a CoPt layer and a Co layer are stacked. As another example, one of the first sub magnetic layer and the second sub magnetic layer may include cobalt (Co), platinum (Pt), and the first nonmagnetic element, and the other one of the first sub magnetic layer and the second sub magnetic layer may include cobalt (Co). The second magnetic layer 134L may be formed to have a multilayer structure in which a CoPtCr layer and a Co layer are stacked.

According to some embodiments, as described with reference to FIG. 7, the first magnetic layer 132L may include a third sub magnetic layer and a sub non-magnetic layer sequentially stacked on the seed layer 120L. For example, the third sub magnetic layer may include cobalt (Co) and platinum (Pt), and the sub non-magnetic layer may include the first non-magnetic element. The first magnetic layer 132L may be formed to have a multilayer structure in which a CoPt layer and a Cr layer are stacked. As another example, the third sub magnetic layer may include cobalt (Co), platinum (Pt), and the first non-magnetic element, and the sub non-magnetic layer may include a second non-magnetic element. The second non-magnetic element may include at least one of Nb, Cr, Mo, W, Zr, Hf, and Ti. The first magnetic layer 132L may be formed to have a multilayer structure in which a CoPtCr layer and a Cr layer are stacked.

The blocking layer 160L may include a first blocking layer 162L and a second blocking layer 164L sequentially stacked on the reference magnetic layer PLa. The first blocking layer 162L may include tungsten (W), and the second blocking layer 164L may include molybdenum (Mo). The first blocking layer 162L may further include a first ferromagnetic element, and the first ferromagnetic element may include at least one of cobalt (Co), iron (Fe), and nickel (Ni). The first blocking layer 162L may further include boron (B). The second blocking layer 164L may further include a second ferromagnetic element, and the second ferromagnetic element may include at least one of cobalt (Co), iron (Fe), and nickel (Ni). The second blocking layer 164L may further include boron (B). The second blocking layer 164L may be formed to have an amorphous phase.

The lower electrode layer BEL, the seed layer 120L, the reference magnetic layer PLa, the blocking layer 160L, the polarization enhancement layer 170L, the tunnel barrier layer TBL, the free magnetic layer (FLa), the upper non-magnetic layer 180L, and the capping layer 190L may be formed by a chemical vapor deposition method or a physical vapor deposition method, for example, and may be formed using a sputtering deposition method. A conductive mask pattern 220 may be formed on the capping layer 190L, and may define a region where a magnetic tunnel junction pattern to be described later is to be formed. The conductive mask pattern 220 may include at least one of a metal (e.g., Ta, W, Ru, Ir, etc.) and a conductive metal nitride (e.g., TiN).

Referring to FIG. 9, the capping layer 190L, the upper nonmagnetic layer 180L, the free magnetic layer FLa, the tunnel barrier layer TBL, the polarization enhancement layer 170L, the blocking layer 160L, and the reference magnetic layer PLa, the seed layer 120L, and the lower electrode layer BEL may be sequentially etched by an etching process using the conductive mask pattern 220 as an etch mask. The etching process may be, for example, an ion beam etching process. As the lower electrode layer BEL, the seed layer 120L, the reference magnetic layer PLa, the blocking layer 160L, the polarization enhancement layer 170L, the tunnel barrier layer TBL, the free magnetic layer FLa, the upper nonmagnetic layer 180L, and the capping layer 190L are etched, a lower electrode BE, a seed pattern 120, a reference magnetic pattern PL, a blocking pattern 160, a polarization enhancement pattern 170, a tunnel barrier pattern TBP, a free magnetic pattern FL, an upper non-magnetic pattern 180, and a capping pattern 190 may be respectively formed. The reference magnetic pattern PL may include a first pinned pattern 130, an exchange coupling pattern 140, and a second pinned pattern 150 formed by etching the first pinned layer 130L, the exchange coupling layer 140L, and the second pinned layer 150L. The first pinned pattern 130 may include a first magnetic pattern 132 and a second magnetic pattern 134 formed by etching the first magnetic layer 132L and the second magnetic layer 134L. The blocking pattern 160 may include a first blocking pattern 162 and a second blocking pattern 164 formed by etching the first blocking layer 162L and the second blocking layer 164L.

The seed pattern 120, the reference magnetic pattern PL, the blocking pattern 160, the polarization enhancement pattern 170, the tunnel barrier pattern TBP, the free magnetic pattern FL, the upper non-magnetic pattern 180, and the capping pattern 190 may be sequentially stacked on the lower electrode BE, and may constitute a magnetic tunnel junction pattern MTJ. After the etching process, a remainder of the conductive mask pattern 220 may remain on the magnetic tunnel junction pattern MTJ. The remainder of the conductive mask pattern 220 may be referred to as an upper electrode TE.

Referring back to FIG. 2, a second interlayer insulating layer 220 may cover side surfaces of the first interlayer insulating layer 110, and the lower electrode BE, the magnetic tunnel junction pattern MTJ, and the upper electrode TE. An upper wiring 210 may be formed on the second interlayer insulating layer 220 and may be connected to the upper electrode TE. The upper wiring 220 may have a line shape extending in the second direction D2.

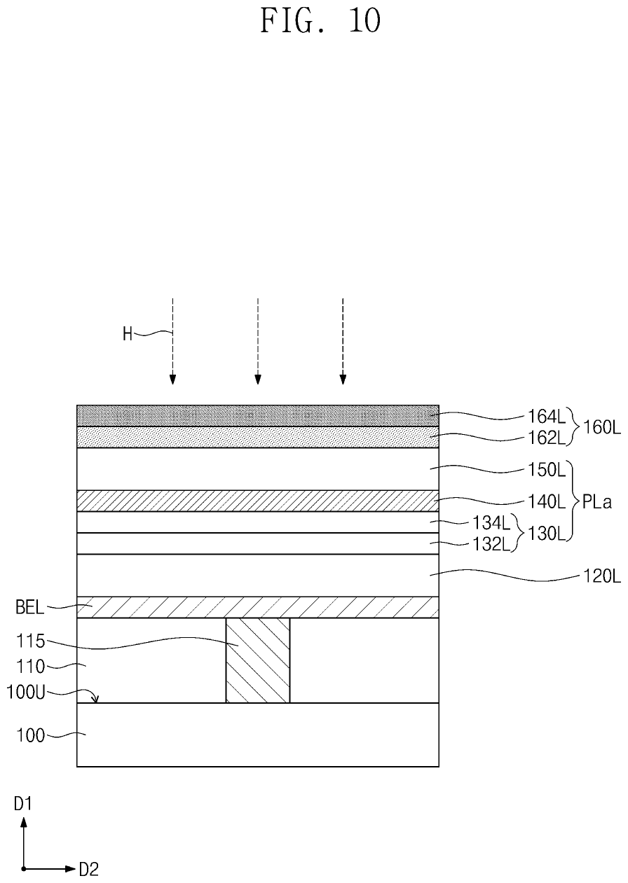

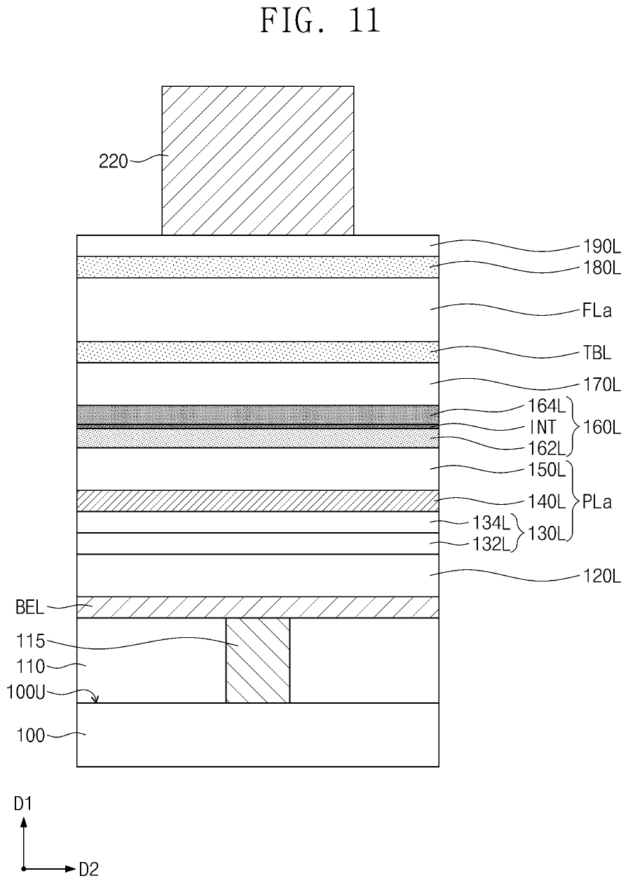

FIGS. 10 and 11 are cross-sectional views illustrating a method of manufacturing a magnetic memory device according to some embodiments of the present disclosure. For simplicity of explanation, differences from the manufacturing method of the magnetic memory device described with reference to FIGS. 8 and 9 will be mainly described. Referring to FIG. 10, the lower electrode layer BEL, the seed layer 120L, the reference magnetic layer PLa, and the blocking layer 160L may be sequentially stacked on the first interlayer insulating layer 110. A heat treatment process H may be performed on the blocking layer 160L, at a temperature of, for example, 400° C. or higher.

Referring to FIG. 11, by the heat treatment process H, elements in the first blocking layer 162L and the second blocking layer 164L may be diffused between the first blocking layer 162L and the second blocking layer 164L, and thus, as described with reference to FIG. 5, the interface layer INT may be formed between the first blocking layer 162L and the second blocking layer 164L. The interface layer INT may include at least one of tungsten (W), molybdenum (Mo), boron (B), the first ferromagnetic element, and the second ferromagnetic element.

After the heat treatment process H, the polarization enhanced layer 170L, the tunnel barrier layer TBL, the free magnetic layer FLa, the upper non-magnetic layer 180L, and the capping layer 190L may be sequentially stacked on the blocking layer 160L. The conductive mask pattern 220 may be formed on the capping layer 190L, and may define a region where a magnetic tunnel junction pattern to be described later is to be formed. Except for the above-mentioned difference, the manufacturing method of the magnetic memory device according to the present embodiments may be substantially the same as the manufacturing method of the magnetic memory device described with reference to FIGS. 8 and 9.

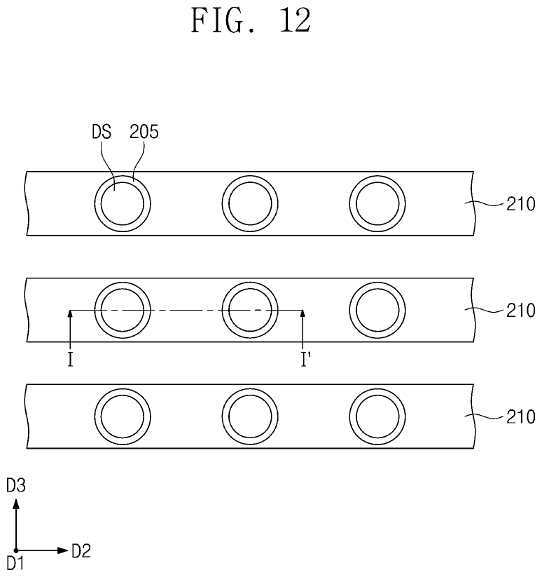

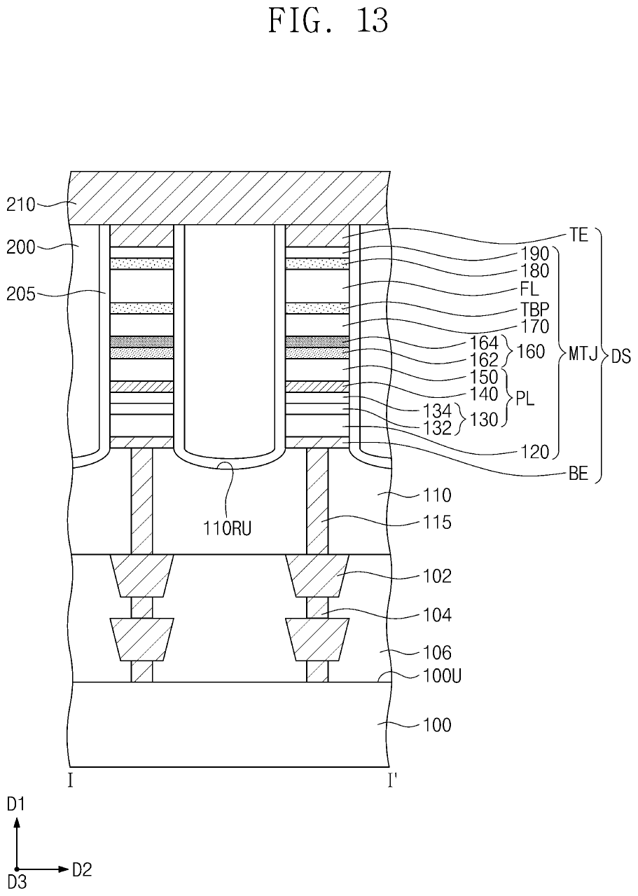

FIG. 12 is a plan view of a magnetic memory device according to some embodiments of the present disclosure, and FIG. 13 is a cross-sectional view taken along line I-I′ of FIG. 12. For simplicity of explanation, descriptions overlapping those of the magnetic memory device described with reference to FIGS. 2 to 7 will be omitted. Referring to FIGS. 12 and 13, lower wirings 102 and lower contacts 104 may extend on a substrate 100. The lower wirings 102 may be spaced apart from an upper surface 100U of the substrate 100 in a first direction D1 perpendicular to the upper surface 100U of the substrate 100. The lower contacts 104 may extend between the lower wirings 102, and between the lowermost lower wirings 102 of the lower wirings 102 and the substrate 100. Each of the lower wirings 102 may be electrically connected to the substrate 100 through a corresponding one of the lower contacts 104. The lower wirings 102 and the lower contacts 104 may include metal (e.g., copper).

The select elements (SE in FIG. 1) may extend in the substrate 100. The selection elements may be, for example, field effect transistors. Each of the lower wirings 102 may be electrically connected to a terminal (e.g., a source/drain terminal) of a corresponding one of the selection elements through a corresponding lower contact 104.

A lower interlayer insulating layer 106 may extend on the substrate 100 and may cover the lower wirings 102 and the lower contacts 104. Upper surfaces of uppermost lower wirings 102 among the lower wirings 102 may be coplanar with an upper surface of the lower interlayer insulating layer 106. The upper surfaces of the lower wirings 102 of the uppermost layer may be positioned at substantially the same height as the upper surface of the lower interlayer insulating layer 106. In this specification, the height means a distance measured in the first direction D1 from the upper surface 100U of the substrate 100. The lower interlayer insulating layer 106 may include, for example, silicon oxide, silicon nitride, and/or silicon oxynitride.

A first interlayer insulating layer 110 may extend on the lower interlayer insulating layer 106 and may cover the upper surfaces of the lower wirings 102 of the uppermost layer. A plurality of lower contact plugs 115 may extend in the first interlayer insulating layer 110. The plurality of lower contact plugs 115 may be spaced apart from each other in the second and third directions D2 and D3 parallel to the upper surface 100U of the substrate 100. The second direction D2 and the third direction D3 may cross each other. Each of the plurality of lower contact plugs 115 may pass through the first interlayer insulating layer 110 and be connected to a corresponding lower wiring 102 among the lower wirings 102. The plurality of lower contact plugs 115 may include at least one of a doped semiconductor material (e.g., doped silicon), a metal (e.g., tungsten, titanium, and/or tantalum), a metal-semiconductor compound (e.g., metal silicide), a conductive material, and a metal nitride (e.g., titanium nitride, tantalum nitride, and/or tungsten nitride).

A plurality of data storage patterns DS may extend on the first interlayer insulating layer 110 and may be spaced apart from each other in the second direction D2 and the third direction D3. The plurality of data storage patterns DS may be respectively disposed on the plurality of lower contact plugs 115 and may be respectively connected to the plurality of lower contact plugs 115.

Each of the plurality of data storage patterns DS may include a lower electrode BE, a magnetic tunnel junction pattern MTJ, and an upper electrode TE sequentially stacked on a corresponding lower contact plug 115. The lower electrode BE may extend between the corresponding lower contact plug 115 and the magnetic tunnel junction pattern MTJ, and the magnetic tunnel junction pattern MTJ may extend between the lower electrode BE and the upper electrode TE. The magnetic tunnel junction pattern MTJ may have the same configuration as the magnetic tunnel junction patterns MTJ described with reference to FIGS. 2 to 7.

According to some embodiments, an upper surface of the first interlayer insulating layer 110 may be recessed toward the substrate 100 between the plurality of data storage patterns DS. A protective insulating layer 205 may surround each side surface of the plurality of data storage patterns DS. The protective insulating layer 205 may cover side surfaces of the lower electrode BE, the magnetic tunnel junction pattern MTJ, and the upper electrode TE, and may surround the side surfaces of the lower electrode BE, the magnetic tunnel junction pattern MTJ, and the upper electrode TE when viewed in a plan view. The protective insulating layer 205 may extend from each side surface of the plurality of data storage patterns DS onto a recessed upper surface 110RU of the first interlayer insulating layer 110. The protective insulating layer 205 may conformally cover the recessed upper surface 110RU of the first interlayer insulating layer 110. The protective insulating layer 205 may include nitride (e.g., silicon nitride).

A second interlayer insulating layer 200 may extend on the first interlayer insulating layer 110 and may cover the plurality of data storage patterns DS. The protective insulating layer 205 may extend between each side surface of the plurality of data storage patterns DS and the second interlayer insulating layer 200, and may extend between the recessed upper surface 110RU of the first interlayer insulating layer 110 and the second interlayer insulating layer 200.

A plurality of upper wirings 210 may extend on the second interlayer insulating layer 200. The plurality of upper wirings 210 may extend in the second direction D2 and may be spaced apart from each other in the third direction D3. Each of the plurality of upper wirings 210 may be connected (e.g., electrically connected) to data storage patterns DS spaced apart from each other in the second direction D2 among the plurality of data storage patterns DS.

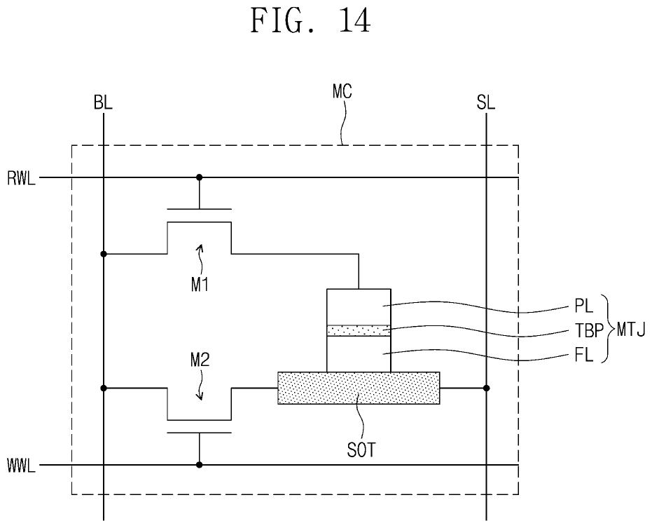

FIG. 14 is a circuit diagram schematically illustrating a memory cell of a magnetic memory device according to some embodiments of the present disclosure. Referring to FIG. 14, a memory cell MC may include a magnetic tunnel junction pattern MTJ, a spin-orbit torque line SOT, a read transistor M1, and a write transistor M2. A first end of the spin-orbit torque line SOT may be connected to a first source/drain terminal of the write transistor M2, and a second end of the spin-orbit torque line SOT may be connected to a source line SL. The magnetic tunnel junction pattern MTJ may extend on the spin-orbit torque line SOT between the first end and the second end. The magnetic tunnel junction pattern MTJ may include a reference magnetic pattern PL, a free magnetic pattern FL, and a tunnel barrier pattern TBP therebetween. The free magnetic pattern FL may extend between the spin-orbit torque line SOT and the tunnel barrier pattern TBP, and the reference magnetic pattern PL may be spaced apart from the free magnetic pattern FL with the tunnel barrier pattern TBP extending therebetween. The free magnetic pattern FL may be in contact with one surface of the spin-orbit torque line SOT. When an in-plane current flows through the spin-orbit torque line SOT, a spin-orbit torque induced by a spin Hall effect or a Rashba effect may be applied to the free magnetic pattern FL, and thus a magnetization direction of the free magnetic pattern FL may be switched.

The magnetic tunnel junction pattern MTJ may extend between the second source/drain terminal of the read transistor M1 and the spin-orbit torque line SOT, and may be connected to the second source/drain terminal of the read transistor M1. Third source/drain terminals of the read transistor M1 and the write transistor M2 may be connected in common to the bit line BL. The read transistor M1 may be connected between the magnetic tunnel junction pattern MTJ and the bit line BL, and a gate electrode of the read transistor M1 may be connected to a read word line RWL. The read transistor M1 may control an electrical connection between the magnetic tunnel junction pattern MTJ and the bit line BL. The write transistor M2 may be connected between the first end of the spin-orbit torque line SOT and the bit line BL, and a gate electrode of the write transistor M2 may be connected to a write word line WWL. The write transistor M2 may control an electrical connection between the spin-orbit torque line SOT and the bit line BL.

During a write operation, the write transistor M2 is turned on through the write word line WWL, and the read transistor M1 may be turned off. Accordingly, a write current may flow through the spin-orbit torque line SOT. A current direction of the write current may be various depending on voltage conditions applied to the bit line BL and the source line SL. The write current may be an in-plane current that applies the spin-orbit torque to the free magnetic pattern FL of the magnetic tunnel junction pattern MTJ. The write current may flow parallel to and adjacent to an interface between the spin-orbit torque line SOT and the free magnetic pattern FL. While the write current flows, a spin current may flow in a direction perpendicular to an interface between the spin-orbit torque line SOT and the free magnetic pattern FL due to the spin Hall effect and the Rashba effect, and thus a spin orbit torque may be applied to the magnetic tunnel junction pattern MTJ. Accordingly, the magnetization direction of the free magnetic pattern FL may be switched antiparallel (or parallel) to the magnetization direction of the reference magnetic pattern PL.

During a read operation, the read transistor M1 may be turned on through the read word line RWL, and the write transistor M2 may be turned off. A read current may flow from the bit line BL to the source line SL. The read current may flow through the magnetic tunnel junction pattern MTJ and the spin-orbit torque line SOT. The read current may flow through the magnetic tunnel junction pattern MTJ in a direction perpendicular to an interface where the spin-orbit torque line SOT and the magnetic tunnel junction pattern MTJ come into contact.

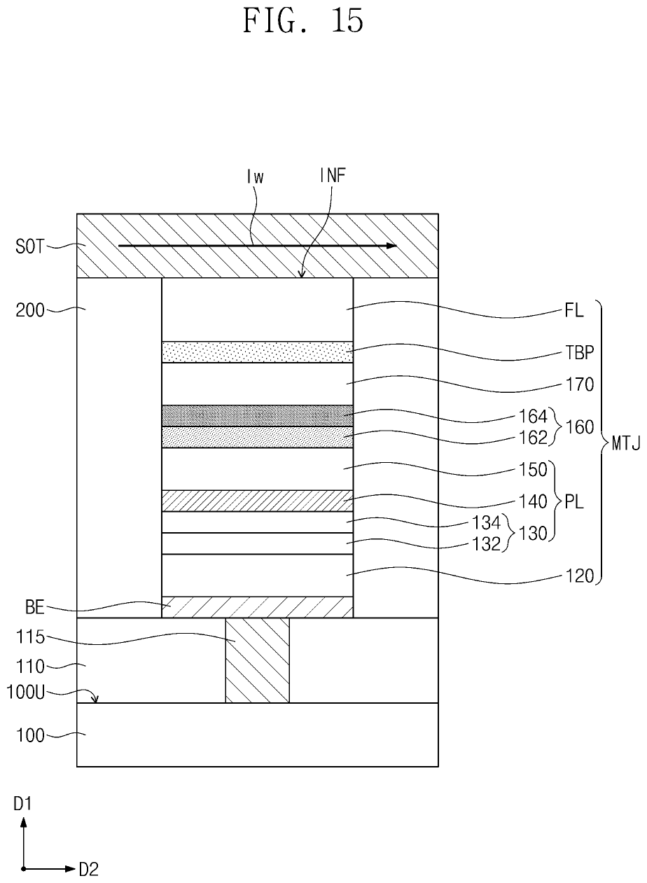

FIG. 15 is a cross-sectional view of a magnetic memory device according to some embodiments of the present disclosure. For simplicity of description, differences from the magnetic memory device described with reference to FIGS. 2 to 7 will be mainly described. Referring to FIG. 15, a first interlayer insulating layer 110 may extend on the substrate 100, and a lower contact plug 115 may extend in the first interlayer insulating layer 110. The lower contact plug 115 may pass through the first interlayer insulating layer 110 and may be electrically connected to the substrate 100. The read transistor M1 of FIG. 14 may extend on the substrate 100, and the lower contact plug 115 may be electrically connected to one terminal (e.g., a source/drain terminal) of the read transistor M1.

A lower electrode BE and a magnetic tunnel junction pattern MTJ may be sequentially stacked on the lower contact plug 115 in a first direction D1 perpendicular to an upper surface 100U of the substrate 100. The lower electrode BE may extend between the lower contact plug 115 and the magnetic tunnel junction pattern MTJ. The lower electrode BE may be electrically connected to the lower contact plug 115.

The magnetic tunnel junction pattern MTJ may include a reference magnetic pattern PL, a free magnetic pattern FL, and a tunnel barrier pattern TBP between the reference magnetic pattern PL and the free magnetic pattern FL. The reference magnetic pattern PL may extend between the lower electrode BE and the tunnel barrier pattern TBP, and the free magnetic pattern FL may be spaced apart from the reference magnetic pattern PL with the tunnel barrier pattern TBP extending therebetween. The reference magnetic pattern PL may include a first pinned pattern 130, a second pinned pattern 150 between the first pinned pattern 130 and the tunnel barrier pattern TBP, and an exchange coupling pattern 140 between the first pinned pattern 130 and the second pinned pattern 150. The first pinned pattern 130 may include a first magnetic pattern 132 and a second magnetic pattern 134 between the first magnetic pattern 132 and the exchange coupling pattern 140.

The magnetic tunnel junction pattern MTJ may further include a seed pattern 120 between the lower electrode BE and the reference magnetic pattern PL, a polarization enhancement pattern 170 between the tunnel barrier pattern TBP and the reference magnetic pattern PL, and a blocking pattern 160 between the polarization enhancement pattern 170 and the reference magnetic pattern PL.

The seed pattern 120, the reference magnetic pattern PL, the blocking pattern 160, the polarization enhancement pattern 170, the tunnel barrier pattern TBP, and the free magnetic pattern FL are substantially the same as the seed pattern 120, the reference magnetic pattern PL, the blocking pattern 160, the polarization enhancement pattern 170, the tunnel barrier pattern TBP, and the free magnetic pattern described with reference to FIGS. 2 to 7.

A second interlayer insulating layer 200 may extend on the first interlayer insulating layer 110 and may cover side surfaces of the lower electrode BE and the magnetic tunnel junction pattern MTJ. A spin-orbit torque line SOT may extend on the second interlayer insulating layer 200 and may be connected to the magnetic tunnel junction pattern MTJ. The free magnetic pattern FL of the magnetic tunnel junction pattern MTJ may extend between the tunnel barrier pattern TBP and the spin-orbit torque line SOT. The spin-orbit torque line SOT may extend adjacent to the free magnetic pattern FL. As described with reference to FIG. 14, a write current Iw may flow through the spin-orbit torque line SOT, and may flow in parallel with and adjacent to an interface INF between the spin-orbit torque line SOT and the free magnetic pattern FL. A spin-orbit torque induced by the write current Iw may be applied to the magnetic tunnel junction pattern MTJ, and thus, a magnetization direction of the free magnetic pattern FL may be switched antiparallel (or parallel) to a magnetization direction of the reference magnetic pattern PL.

The spin orbital torque line SOT may include a heavy metal or a material doped with a heavy metal. For example, the spin orbital torque line SOT may include at least one of ‘A’ and ‘M’ doped with ‘B’. ‘A’ may include yttrium (Y), zirconium (Zr), niobium (Nb), molybdenum (Mo), technetium (Tc), ruthenium (Ru), rhodium (Rh), palladium (Pd), cadmium (Cd), indium (In), antimony (Sb), tellurium (Te), hafnium (Hf), tantalum (Ta) (including high-resistance amorphous β-Ta), tungsten (W), rhenium (Re), osmium (Os), Iridium (Ir), platinum (Pt), gold (Au), mercury (Hg), thallium (TI), lead (Pb), bismuth (Bi), polonium (Po), astatine (At), and/or combinations thereof. ‘B’ may include at least one of vanadium (V), chromium (Cr), manganese (Mn), iron (Fe), cobalt (Co), nickel (Ni), phosphorus (P), sulfur(S), zinc (Zn), gallium (Ga), Germanium (Ge), Arsenic (As), Selenium (Se), Yttrium (Y), Zirconium (Zr), Niobium (Nb), Molybdenum (Mo), Technetium (Tc), Ruthenium (Ru), Rhodium (Rh), palladium (Pd), silver (Ag), cadmium (Cd), indium (In), antimony (Sb), tellurium (Te), iodine (I), lutetium (Lu), hafnium (Hf), Tantalum (Ta), Tungsten (W), Rhenium (Re), Osmium (Os), Iridium (Ir), Platinum (Pt), Gold (Au), Mercury (Hg), Thallium (TI), Lead (Pb), bismuth (Bi), polonium (Po), astatine (At), lanthanum (La), cerium (Ce), praseodymium (Pr), neodymium (Nd), promethium (Pm), samarium (Sm), europium (Eu)), gadolinium (Gd), terbium (Tb), dysprosium (Dy), holmium (Ho), erbium (Er), thulium (Tm), and ytterbium (Yb). ‘M’ may include at least one of aluminum (Al), titanium (Ti), vanadium (V), chromium (Cr), manganese (Mn), copper (Cu), zinc (Zn), silver (Ag), hafnium (Hf), tantalum (Ta), tungsten (W), rhenium (Re), platinum (Pt) gold (Au), mercury (Hg), lead (Pb), silicon (Si), gallium (Ga), gallium manganese (GaMn), or gallium arsenic (GaAs).

The spin orbital torque line SOT may include a topological insulator based on a chalcogen element. The spin-orbit torque line SOT may include a compound in which at least one of tellurium (Te) and selenium (Se) is combined with at least one of silicon (Si), germanium (Ge), bismuth (Bi), and antimony (Sb). For example, the spin-orbit torque line SOT may include at least one of GeSe, BiSe, BiSbTe, GeTe, GeTeSe, GeSbTe, SiTe, and SiGeTe. The magnetic tunnel junction pattern MTJ and the spin-orbit torque line SOT may constitute the memory cell MC of FIG. 14.

According to the concept of the present disclosure, the first pinned pattern of the reference magnetic pattern having the composite antiferromagnetic coupling structure may include cobalt (Co), platinum (Pt), and the first non-magnetic element. As the first pinned pattern includes the first non-magnetic element, the first pinned pattern may have the relatively low saturation magnetization (Mst) and the relatively high coercive force (Hc). Accordingly, the exchange coupling characteristics of the reference magnetic pattern may be improved, and the heat tolerance for the high temperature process of 400° C. or higher may be increased. In addition, as the first pinned pattern includes the first non-magnetic element, the surface roughness of the first pinned pattern may be reduced.

In addition, the blocking pattern disposed between the reference magnetic pattern and the polarization enhancement pattern may have the multilayer structure including the first blocking pattern containing tungsten and the second blocking pattern containing molybdenum. The second blocking pattern may have the amorphous phase. Accordingly, the diffusion of boron in the magnetic tunnel junction pattern may be prevented, and the crystallinity of the reference magnetic pattern PL may be blocked from being transferred to the polarization enhancement pattern 170. As the first blocking pattern and the second blocking pattern each include tungsten and molybdenum having the relatively high melting points, deterioration of the crystallinity of the reference magnetic pattern and the polarization enhancement pattern may be prevented, and the tunnel magnetoresistance characteristics of the magnetic tunnel junction pattern may be improved, even when the high-temperature process of 400° C. or more is performed.

Accordingly, the tunnel magnetoresistance (TMR) characteristics and the exchange coupling characteristics of the magnetic tunnel junction pattern may be improved, and the high-temperature reliability of the magnetic memory device including the magnetic tunnel junction pattern may be improved.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A magnetic memory device, comprising:
a reference magnetic pattern and a free magnetic pattern stacked in vertical alignment relative to a surface of a substrate; and
a tunnel barrier pattern extending between the reference magnetic pattern and the free magnetic pattern;
wherein the reference magnetic pattern includes:
a first pinned pattern, and a second pinned pattern extending between the first pinned pattern and the tunnel barrier pattern; and
an exchange coupling pattern, which extends between the first pinned pattern and the second pinned pattern and antiferromagnetically couples the first pinned pattern and the second pinned pattern to each other;
wherein the first pinned pattern includes a first magnetic pattern and a second magnetic pattern extending between the first magnetic pattern and the exchange coupling pattern;
wherein one of the first magnetic pattern and the second magnetic pattern comprises: cobalt, platinum, and a first non-magnetic element comprising at least one of Nb, Cr, Mo, W, Zr, Hf, and Ti; and
wherein the other one of the first magnetic pattern and the second magnetic pattern comprises cobalt.

2. The magnetic memory device of claim 1, wherein the second pinned pattern comprises cobalt.

3. The magnetic memory device of claim 1, further comprising:
a polarization enhancement pattern extending between the tunnel barrier pattern and the reference magnetic pattern; and
a blocking pattern extending between the polarization enhancement pattern and the reference magnetic pattern, said blocking pattern having at least a portion therein that is amorphous.

4. The magnetic memory device of claim 3,
wherein the blocking pattern includes: a first blocking pattern, and a second blocking pattern extending between the first blocking pattern and the polarization enhancement pattern; and
wherein the first blocking pattern comprises tungsten, and the second blocking pattern comprises molybdenum.

5. The magnetic memory device of claim 4, wherein the second blocking pattern is amorphous.

6. The magnetic memory device of claim 4, wherein the second blocking pattern further comprises a ferromagnetic element.

7. The magnetic memory device of claim 6,
wherein the second blocking pattern further comprises boron; and
wherein a concentration of the molybdenum in the second blocking pattern is smaller than a concentration of boron in the second blocking pattern.

8. The magnetic memory device of claim 4, wherein the first blocking pattern further comprises a ferromagnetic element and boron.

9. The magnetic memory device of claim 3, wherein the polarization enhancement pattern comprises CoFeB.

10. The magnetic memory device of claim 1,
wherein the first pinned pattern has a first perpendicular magnetization direction perpendicular to an interface between the free magnetic pattern and the tunnel barrier pattern; and
wherein the second pinned pattern has a second perpendicular magnetization direction antiparallel to the first perpendicular magnetization direction.

11. The magnetic memory device of claim 1,
wherein the first magnetic pattern includes:
a sub magnetic pattern comprising cobalt and platinum; and
a sub non-magnetic pattern, which extends between the sub magnetic pattern and the second magnetic pattern and comprises the first non-magnetic element; and
wherein the second magnetic pattern comprises cobalt.

12. The magnetic memory device of claim 11,
wherein the sub magnetic pattern further comprises a second non-magnetic element; and
wherein the second non-magnetic element comprises at least one of Nb, Cr, Mo, W, Zr, Hf, and Ti.

13. The magnetic memory device of claim 11, wherein the second magnetic pattern further comprises at least one of platinum and the first non-magnetic element.

14. The magnetic memory device of claim 1,
wherein the first magnetic pattern comprises cobalt, platinum, and the first non-magnetic element;
wherein the second magnetic pattern comprises:
a first sub magnetic pattern; and
a second sub magnetic pattern extending between the first sub magnetic pattern and the exchange coupling pattern; and
wherein one of the first sub magnetic pattern and the second sub magnetic pattern comprises cobalt, and the other one of the first sub magnetic pattern and the second sub magnetic pattern comprises cobalt and platinum.

15. The magnetic memory device of claim 14, wherein the other one of the first sub magnetic pattern and the second sub magnetic pattern further comprises the first non-magnetic element.

16. The magnetic memory device of claim 1,
wherein the first magnetic pattern comprises cobalt and platinum,
wherein the second magnetic pattern includes:
a first sub magnetic pattern; and
a second sub magnetic pattern extending between the first sub magnetic pattern and the exchange coupling pattern;
wherein one of the first sub magnetic pattern and the second sub magnetic pattern comprises cobalt, and the other one of the first sub magnetic pattern and the second sub magnetic pattern comprises cobalt, platinum and the first non-magnetic element.

17. A magnetic memory device, comprising:
a reference magnetic pattern and a free magnetic pattern stacked in vertical alignment relative to a surface of a substrate;
a tunnel barrier pattern extending between the reference magnetic pattern and the free magnetic pattern;
a polarization enhancement pattern extending between the reference magnetic pattern and the tunnel barrier pattern; and
a blocking pattern extending between the reference magnetic pattern and the polarization enhancement pattern;
wherein the blocking pattern comprises:
a first blocking pattern comprising tungsten; and
a second blocking pattern, which extends between the first blocking pattern and the polarization enhancement pattern, and comprises a ferromagnetic element and molybdenum;
wherein the second blocking pattern is in contact with the polarization enhancement pattern;
wherein the reference magnetic pattern includes a first pinned pattern, and a second pinned pattern extending between the first pinned pattern and the blocking pattern; and
an exchange coupling pattern extending between the first pinned pattern and the second pinned pattern; and
wherein the first pinned pattern comprises: cobalt, platinum, and a first non-magnetic element comprising at least one of Nb, Cr, Mo, W, Zr, Hf, and Ti.

18. The magnetic memory device of claim 17, wherein the first blocking pattern is in contact with the second pinned pattern.

19. The magnetic memory device of claim 17, wherein the second blocking pattern is amorphous.

20. The magnetic memory device of claim 17,
wherein the first pinned pattern includes a first magnetic pattern and a second magnetic pattern between the first magnetic pattern and the exchange coupling pattern;
wherein one of the first magnetic pattern and the second magnetic pattern includes cobalt, platinum, and the first non-magnetic element, and
wherein the other one of the first magnetic pattern and the second magnetic pattern includes cobalt.
